(19) United States
(12) Patent Application Publication
(10) Pub. No.: US 2010/0139967 A1
(43) Pub. Date: Jun. 10, 2010

(54) WIRING BOARD AND FABRICATION METHOD THEREFOR

(75) Inventor: Michimasa Takahashi, Ogaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: IBIDEN CO., LTD., Ogaki-shi (JP)

(21) Appl. No.: 12/537,656

(22) Filed: Aug. 7, 2009

(30) Foreign Application Priority Data
Dec. 8, 2008 (JP) 2008-312702

(51) Int. Cl. H01R 12/04; H05K 3/10

(52) U.S. Cl. 174/262; 29/846

(57) ABSTRACT

A wiring board includes an insulating board, wiring sub boards, and insulating layers having via holes in which conductors are formed by plating. The insulating board and the wiring sub boards are horizontally laid out. The insulating layers are laid out to respectively cover a first boundary portion between the insulating board and each of the wiring sub boards, and a second boundary portion between the wiring sub boards, and continuously extend from the insulating board to wiring sub boards. Resins which constitute the insulating layers are filled in the first boundary portion and the second boundary portion. The conductors are electrically connected to the wiring layers.

### CROSS REFERENCE TO RELATED APPLICATIONS

The present application claims the benefits of priority to Japanese Patent Application No. 2008-312702, which was filed on Dec. 8, 2008. The entire contents of Japanese Patent Application No. 2008-312702 are herein incorporated by reference.

### BACKGROUND OF THE INVENTION

1. Field of the Invention

The present invention relates to a wiring board having an insulating board and a plurality of wiring sub boards, and a method of fabricating the wiring board.

2. Description of the Related Art

For example, Unexamined Japanese Patent Application Publication No. 2002-289986, Unexamined Japanese Patent Application Publication No. 2002-232089, Unexamined Japanese Patent Application Publication No. 2003-69190, Unexamined Japanese Patent Application Publication No. 2007-115855 and Unexamined Japanese Patent Application Publication No. 2005-322878 describe wiring boards and fabrication methods therefor. Those wiring boards each have an insulating board and wiring sub boards connected to the insulating board.

The contents of Unexamined Japanese Patent Application Publication No. 2002-289986, Unexamined Japanese Patent Application Publication No. 2002-232089, Unexamined Japanese Patent Application Publication No. 2003-69190, Unexamined Japanese Patent Application Publication No. 2007-115855 and Unexamined Japanese Patent Application Publication No. 2005-322878 are herein incorporated in their entirety.

### SUMMARY OF THE INVENTION

According to the first aspect of the invention, a wiring board includes: multiple wiring sub boards being laid out side by side with each other and having conductive patterns; an insulating board being laid out alongside of one of the wiring sub boards; and multiple insulating layers having via holes in which conductors electrically connected to the conductive patterns are formed by plating, the insulating layers continuously extending from the insulating board to the wiring sub boards so as to respectively cover a first boundary portion between the insulating board and each of the wiring sub boards, and a second boundary portion between the wiring sub boards. An insulating material for the insulating layers is filled in the first boundary portion and the second boundary portion.

According to the second aspect of the invention, a fabrication method for a wiring board includes: horizontally laying an insulating board and multiple wiring sub boards having conductive patterns; laying multiple insulating layers to respectively cover a first boundary portion between the insulating board and each of the wiring sub boards, and a second boundary portion between the wiring sub boards; filling an insulating material for the insulating layers in the first boundary portion and the second boundary portion; forming via holes in the insulating layers and forming conductors in the via holes by plating; and electrically connecting the conductors formed in the via holes to the conductive patterns.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a diagram showing the outline of a wiring board according to one embodiment of the present invention;

FIG. 1B is a diagram showing the internal structure of the wiring board according to the first embodiment of the invention;

FIG. 2A is a cross-sectional view of a first wiring sub board constituting the wiring board;

FIG. 2B is a cross-sectional view of a second wiring sub board constituting the wiring board;

FIG. 2C is a cross-sectional view of a third wiring sub board constituting the wiring board;

FIG. 3 is a cross-sectional view of a flexible part;

FIG. 4 is a partly enlarged diagram of FIG. 2C;

FIG. 5 is a cross-sectional view along line A-A in FIG. 1A;

FIG. 6 is a diagram showing a production panel for the first wiring sub board;

FIGS. 7A-7C are diagrams for explaining a step of forming a first layer of the first wiring sub board;

FIGS. 8A-8C are diagrams for explaining a step of forming a second layer of the first wiring sub board;

FIGS. 9A-9B are diagrams for explaining a step of forming a third layer of the first wiring sub board;

FIG. 10 is a diagram showing a production panel for the second wiring sub board;

FIG. 11 is a diagram for explaining a step of fabricating the second wiring sub board;

FIG. 12 is a diagram showing a production panel for the third wiring sub board;

FIG. 13 is a cross-sectional view of the third wiring sub board;

FIG. 14 is a diagram for explaining a step of fabricating the core of the third wiring sub board;

FIGS. 15A-15D are diagrams for explaining a step of forming a first layer of the third wiring sub board;

FIGS. 16A-16D are diagrams for explaining a step of forming a second layer of the third wiring sub board;

FIG. 17 is a diagram for explaining a step of fabricating the insulating board;

FIG. 18 is a diagram for explaining a step of laying out the wiring sub boards;

FIGS. 19A-19D are diagrams for explaining a step of forming insulating layers on both sides of the insulating board and the wiring sub boards;

FIGS. 20A-20C are diagrams for explaining a step of forming spaces in the top and bottom of a flexible part;

FIG. 21 is a diagram for explaining a step of performing outline processing on the wiring sub board;

FIG. 22A is a diagram showing another example of the wiring sub board;

FIG. 22B is a diagram showing a different example of the wiring sub board;

FIG. 23A is a diagram showing a further example of the wiring sub board;

FIG. 23B is a diagram showing a still further example of the wiring sub board; and

FIG. 24 is a diagram showing another example of the wiring board.

### DETAILED DESCRIPTIONS OF THE PREFERRED EMBODIMENT

The embodiment will now be described with reference to the accompanying drawings, wherein like reference numerals designate corresponding or identical elements throughout the various drawings.

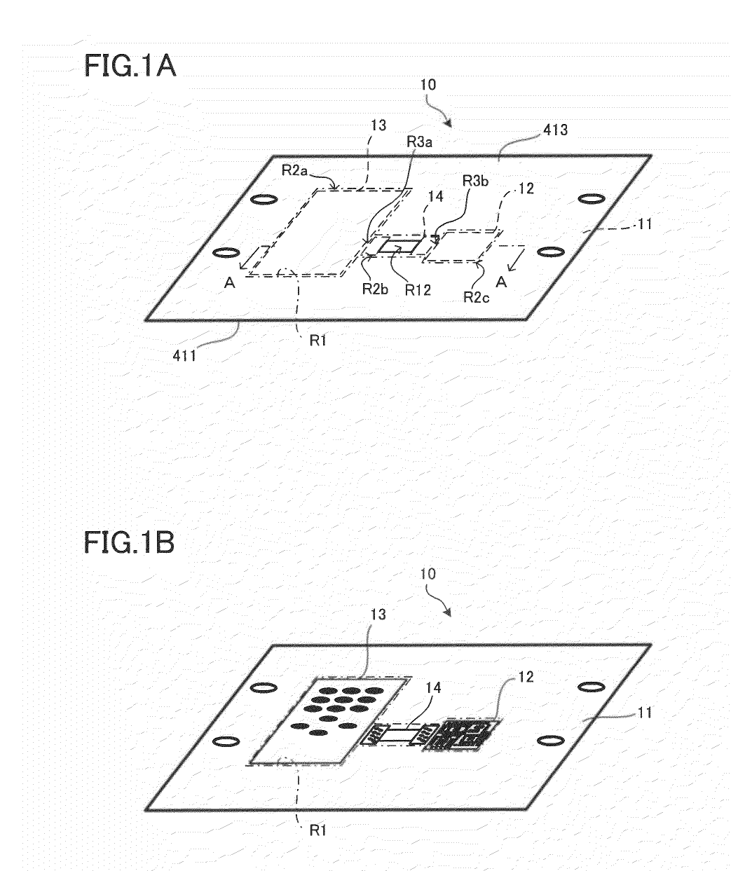

A wiring board 10 according to the embodiment, which has the outline as shown in FIG. 1A and the internal structure as shown in FIG. 1B, for example, has an insulating board 11 as a frame, and wiring sub boards 12, 13 and 14. The insulating board 11 and the wiring sub boards 12 to 14 are laid out horizontally through first boundary portions R2a, R2b, R2c, and the wiring sub boards 12 to 14 are laid out horizontally through second boundary portions R3a, R3b. Insulating layers 413, 411 are formed on the top sides and bottom sides of the insulating board 11 and the wiring sub boards 12 to 14. FIG. 1B shows the internal structure of the wiring board 10 with the insulating layers 411 and 413 omitted.

The insulating board 11 is a rectangular insulating board made of, for example, a glass epoxy resin or the like. Particularly, as shown in FIGS. 1A and 1B, the insulating board 11 has a space (clearance) R1 having a shape corresponding to the outer shapes of the wiring sub boards 12 to 14. The wiring sub boards 12 to 14 are laid out in the space R1 of the insulating board 11. The shape of the insulating board 11 is optional. For example, the shape may be a circular frame, an elliptical frame or a quadrate frame, or may be two thin elongated bars sandwiching the wiring sub boards 12 to 14 aligned in a row.

The wiring sub boards 12 to 14 are rectangular rigid wiring sub boards. The shapes of the wiring sub boards 12 to 14 are optional, and may be, for example, a parallelepiped shape, a circular shape, an elliptical shape or so. The wiring sub boards 12 to 14 are not electrically connected to one another.

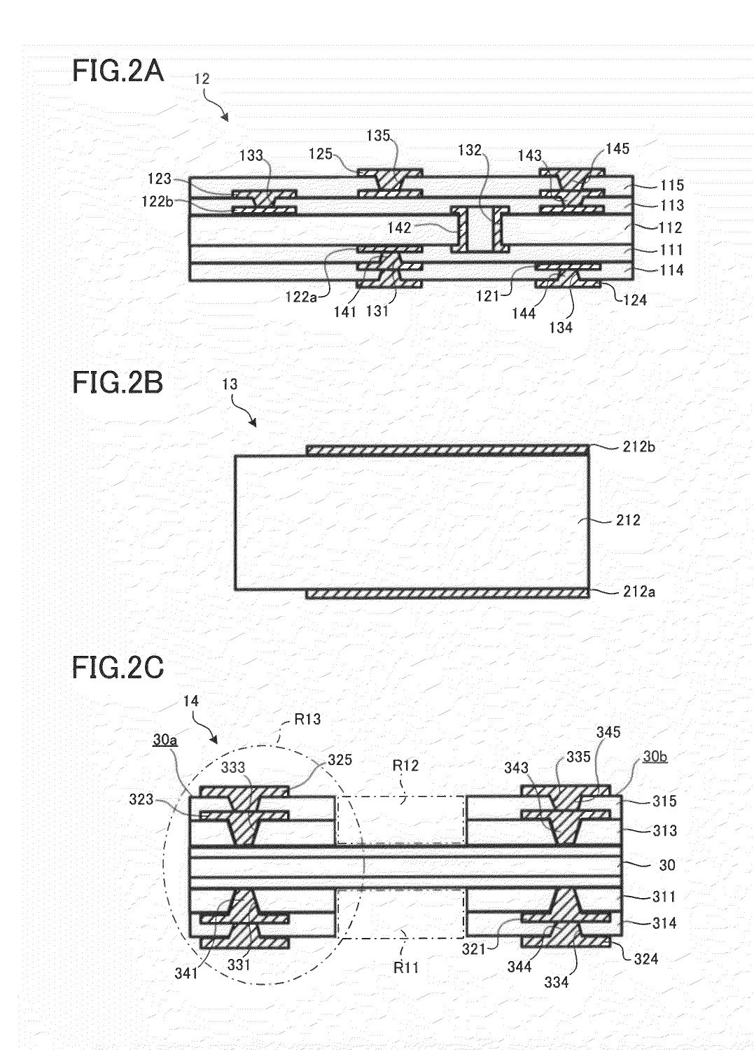

The wiring sub board 12 whose cross-sectional structure is shown in FIG. 2A is a build-up multi-layer rigid wiring sub board. That is, the wiring sub board 12 has a rigid base 112, first and second insulating layers 111 and 113, and third and fourth insulating layers 114 and 115 laminated.

The rigid base 112 is made of, for example, a rigid insulating material. Specifically, the rigid base 112 is made of a glass epoxy resin or the like with a thickness of, for example, about 50 to 150 μm, desirably about 100 μm.

Formed at top and bottom sides of the rigid base 112 are first to fourth insulating layers 111, 113 to 115 made of, for example, a hardened prepreg, wiring layers 122a, 122b, 121, 123 to 125 made of, for example, copper, and via holes (interlayer connected portions) 131, 133 to 135. Conductors 141, 143 to 145 of, for example, copper, are filled in the via holes 131, 133 to 135 to electrically connect the individual wiring layers to one another. A through hole 132 is formed in the rigid base 112. The through hole 132 is formed by, for example, boring a hole in the conductor 142 of copper or the like through and plating the hole to electrically connect the wiring layers 122a and 122b at the top and bottom of the rigid base 112.

The wiring layers 122b, 122a are respectively formed on the top and bottom sides of the rigid base 112, and are electrically connected to the overlying respective wiring layers 121, 123 through the via holes 131, 133 and the conductors 141, 143. Further, the wiring layers 121, 123 are electrically connected to the overlying respective wiring layers 124, 125 through the via holes 134, 135 and the conductors 144, 145.

The wiring sub board 13 whose cross-sectional structure is shown in FIG. 2B is a single-layer rigid wiring sub board. That is, the wiring sub board 13 has a rigid base 212, and insulating layers 212a and 212b. The insulating layers 212a and 212b are formed on the respective sides of the rigid base 212.

The wiring sub board 14 whose cross-sectional structure is shown in FIG. 2C is a build-up multi-layer rigid wiring sub board. A first rigid part 30a and a second rigid part 30b are connected to a flexible part 30 at the core portions of the first and second rigid parts 30b and 30a. A first insulating layer 311 and a second insulating layer 313 hold the ends of the flexible part 30 to support and fix the flexible part 30. Spaces R11 and R12 (FIG. 2C) for bending (deformation) of the flexible part 30 are formed above and below (lamination direction of the insulating layers) at the center portion of the flexible part 30. This allows the wiring sub board 14 to be bent at the center portion of the flexible part 30.

The first and second rigid parts 30b and 30a are formed by laminating the first and second insulating layers 311 and 313, and third and fourth insulating layers 314 and 315 at the core of the flexible part 30 including the end portions. Particularly, wiring layers formed on both sides of the flexible part 30 are electrically connected to overlying respective wiring layers 321, 323 through via holes 331, 333, formed in the first and second insulating layers 311, 313, and conductors 341, 343. Further, the wiring layers 321, 323 are electrically connected to overlying respective wiring layers 324, 325 through via holes 334, 335, formed in the third and fourth insulating layers 314, 315, and conductors 344, 345. The first to fourth insulating layers 311, 313 to 315 are made of, for example, a hardened prepreg. The via holes 331, 333 to 335 are formed to have tapered shapes. The wiring layers 321, 323 to 325 are formed of, for example, copper.

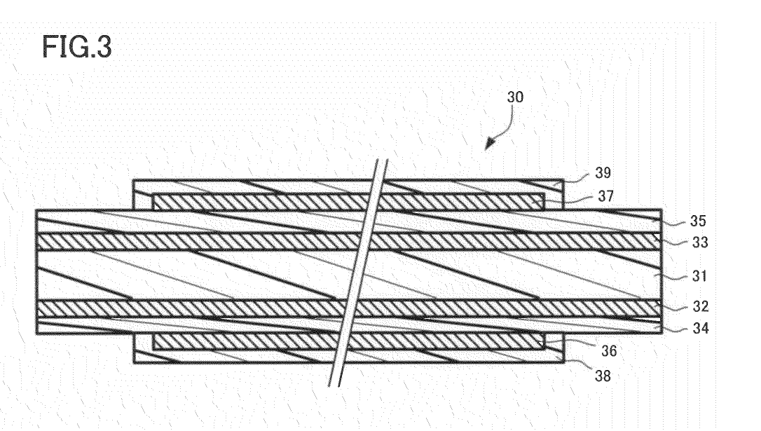

As shown in FIG. 3, for example, the flexible part 30 has a structure having a flexible base 31, conductive layers 32 and 33, insulating films 34 and 35, shield layers 36 and 37, and cover lays 38 and 39 laminated one on another.

The flexible base 31 includes an insulative flexible sheet, for example, a polyimide sheet with a thickness of, for example, about 20 to 50 μm, desirably about 30 μm.

The conductive layers 32 and 33 each have a copper pattern with a thickness of, for example, about 5 to 15 μm. The conductors 33, 32 are respectively formed on the top and bottom sides of the flexible base 31, thus forming the above-described striped wiring pattern.

The conductive layers 34 and 35 each include a polyimide film with a thickness of, for example, about 5 to 15 μm. The conductors 34 and 35 insulate the conductors 32 and 33 from outside.

The shield layers 36 and 37 each include a conductive layer, e.g., a silver-pasted hardened film. The shield layers 36 and 37 shield the conductive layers 32 and 33 from external electromagnetic noise, and shield outside from electromagnetic noise from the conductive layers 32 and 33.

The cover lays 38 and 39 each include an insulating film of polyimide or the like with a thickness of, for example, about 5 to 15 μm. The cover lays 38 and 39 insulate and protect the entire flexible part 30 from outside.

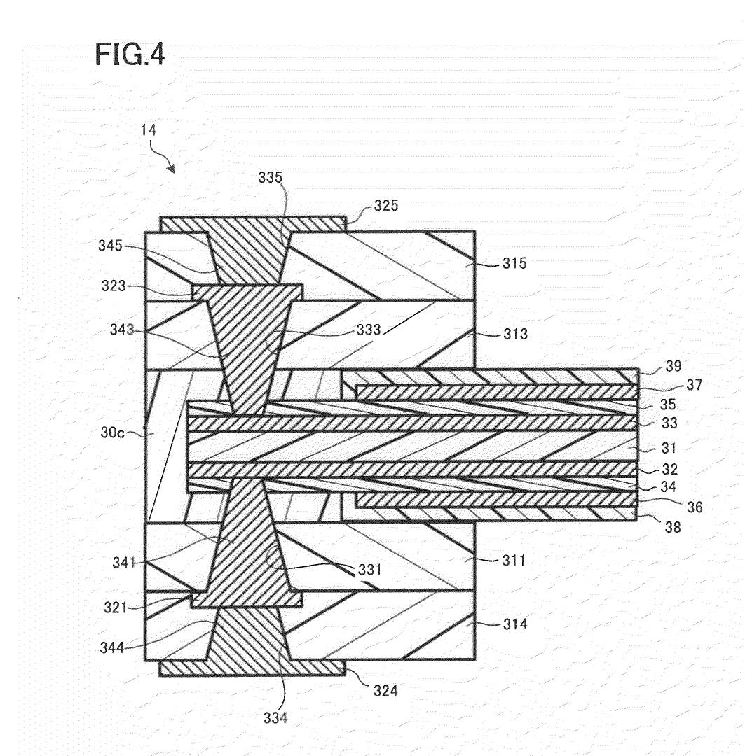

At the portion where the first rigid part 30a and the flexible part 30 are connected together, the first and second insulating layers 311 and 313 cover the flexible part 30 from both the top and bottom sides, and a part of the flexible part 30 is exposed as shown in FIG. 4 showing a region R13 in FIG. 2C in enlargement. The first and second insulating layers 311 and 313 are polymerized with the cover lays 38 and 39 provided on the top surface of the flexible part 30.

The space between the first and second insulating layers 311 and 313 has a resin 30c filled therein, excluding the region of the flexible part 30. The resin 30c is what runs out from the prepregs constituting the first and second insulating layers 311 and 313. The resin 30c is hardened integrally with the first and second insulating layers 311 and 313.

The via holes 331 and 333 are formed in that portion of the flexible part 30 where the shield layers 36 and 37 and the cover lays 38 and 39 are removed. Those via holes 331 and 333 are respectively formed through the insulating films 34 and 35 to expose the conductive layers 32 and 33.

The conductors 341, 343 (plated films) both plated with copper, for example, are filled in the via holes 331, 333. The conductors 341, 343 allow the wiring layers 321, 323 of the first rigid part 30a to be electrically connected to the conductive layers 32, 33 of the flexible part 30.

While the details of the structure of the connected portion of the first rigid part 30a and the flexible part 30 (FIG. 4) are given above, the structure of the connected portion of the second rigid part 30b and the flexible part 30 is the same.

As apparent from the above, the first and second rigid parts 30b and 30a are electrically connected to the flexible part 30 without using connectors. Accordingly, even when the wiring sub board 14 is dropped or so to be applied with shocks, a contact failure originating from disconnection of such connectors does not occur.

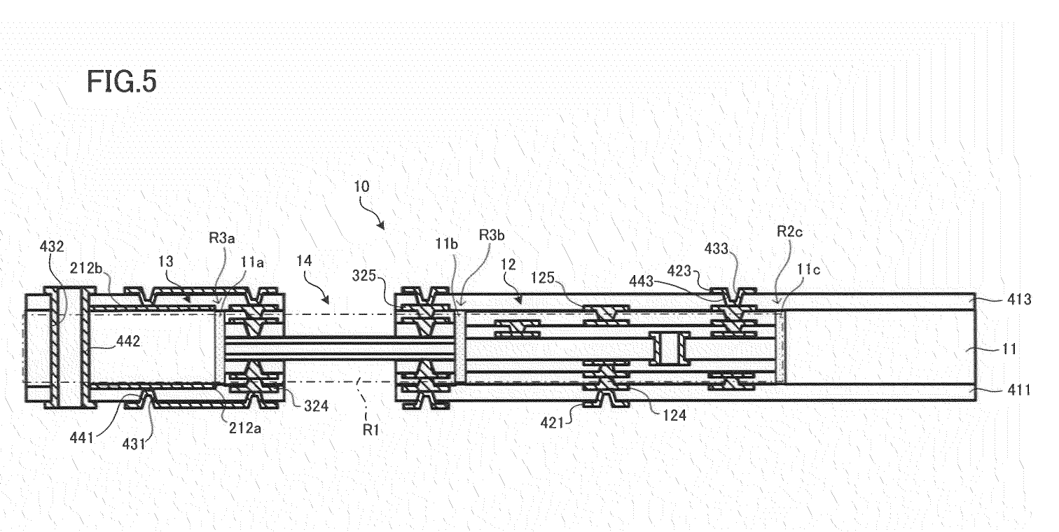

As shown in FIG. 5 (cross-sectional view along line A-A in FIG. 1A), for example, the insulating layers 413, 411 are respectively formed on the top and bottom sides of the insulating board 11 and the wiring sub boards 12 to 14. The insulating layers 411, 413 are laid out to cover the first boundary portions R2a, R2b and R2c (FIG. 1A) between the insulating board 11 and the wiring sub boards 12 to 14, and the second boundary portions R3a and R3b between the wiring sub boards 12 to 14. The insulating layers 411 and 413 continuously extend from the insulating board 11 to the wiring sub boards 12 to 14.

Via holes 431, 433 are formed in the insulating layers 411, 413, respectively. Conductors 441, 443 of copper, for example, are formed in the via holes 431, 433. The conductors 441, 443 are electrically connected to the wiring layers 212a, 212b, 324, 325, 124, 125 of the wiring sub boards 12 to 14, respectively. Note that the wiring sub boards 12 to 14 are not electrically connected to one another.

The insulating layers 411 and 413 are formed of a rigid insulating material, such as a hardened prepreg. It is desirable that the prepregs of the first to fourth insulating layers 111 and 113 to 115, the first to fourth insulating layers 311 and 313, the third and fourth insulating layers 314 and 315, and the insulating layers 411 and 413 should contain a resin having the low-flow property. Such prepregs can be produced by performing pre-hardening beforehand by, for example, impregnating a glass cloth with an epoxy resin, then thermally hardening the resin. The glass cloth may be impregnated with a high viscosity resin, or impregnated with a resin containing an inorganic filler (e.g., silica filler), or the resin contain of the glass cloth may be decreased. An RCF (Resin Coated cupper Foil) or the like may be used in place of the prepreg.

Resins 11a to 11c (insulating materials) leaked out (flowed out) from the insulating layers 411 and 413 are filled in the first boundary portions R2a, R2b and R2c (FIG. 1A) between the insulating board 11 and the wiring sub boards 12 to 14, and the second boundary portions R3a and R3b between the wiring sub boards 12 to 14. Accordingly, the wiring sub boards 12 to 14 are secured at predetermined positions. This therefore requires no bridges or the like to couple the insulating board 11 to the wiring sub boards 12 to 14. The use of the resins 11a to 11c leaked from the insulating layers 411 and 413 also eliminates the need for an adhesive or the like.

Further, the wiring board 10 has a through hole 432. A conductor 442 is formed in the through hole 432. The conductor 442 electrically connects the conductive patterns on both sides (two major surfaces) of the wiring board 10.

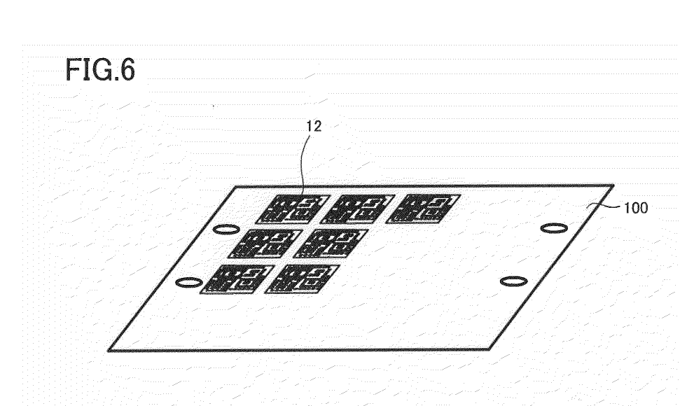

In fabricating the wiring board 10, first, the wiring sub board 12 is produced at a production panel 100 as shown in FIG. 6, for example. The production panel 100 is a dedicated production panel at which wiring sub boards having the same structure (structure shown in FIG. 2A) are produced.

The insulating board 11 and the wiring sub board 12 may have different structures due to differences in, for example, the number of insulating layers and materials for the insulating layers (e.g., flexible base and rigid base). In this respect, the wiring sub board 12 is produced separately from the insulating board 11 according to the fabrication method of the embodiment, the insulating boards 11 or the wiring sub boards 12 having the same structure are produced at the production panel 100 even in such a case. This makes it possible to produce a larger number of wiring sub boards at the production panel 100, thus improving the yield or the number of yielded products.

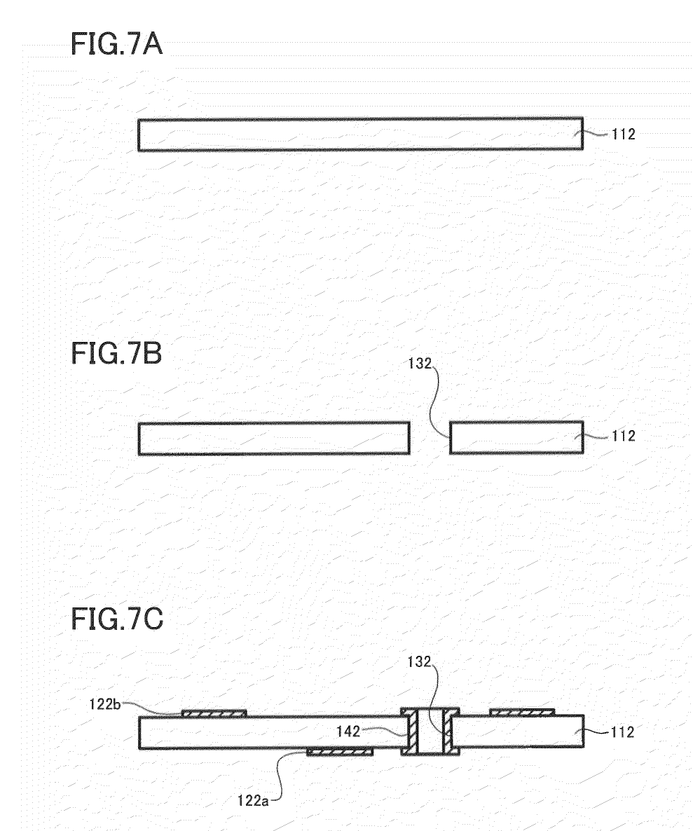

In producing the wiring sub board 12, first, a material common to multiple products is cut with, for example, a laser or the like to prepare the rigid base 112 with a predetermined shape and size as shown in FIG. 7A.

Then, after predetermined pre-processing, for example, the through hole 132 is formed as shown in FIG. 7B by irradiating, for example, a CO₂ laser beam from a CO₂ laser processing apparatus.

Subsequently, after desmearing (smear removal) and soft etching are carried out, PN plating (e.g., chemical copper plating and electric copper plating) is performed. As a result, a conductive film is formed on the entire surface of the rigid base 112 including the interior of the through hole 132. Then, the conductive film is made thinner to a predetermined thickness by, for example, half etching, the conductive film is patterned as shown in FIG. 7C through, for example, a predetermined lithography process (pre-processing, lamination, exposure, development, etching, film separation, inspection of internal layers, etc.). As a result, the wiring layers 122a and 122b and the conductor 142 are formed.

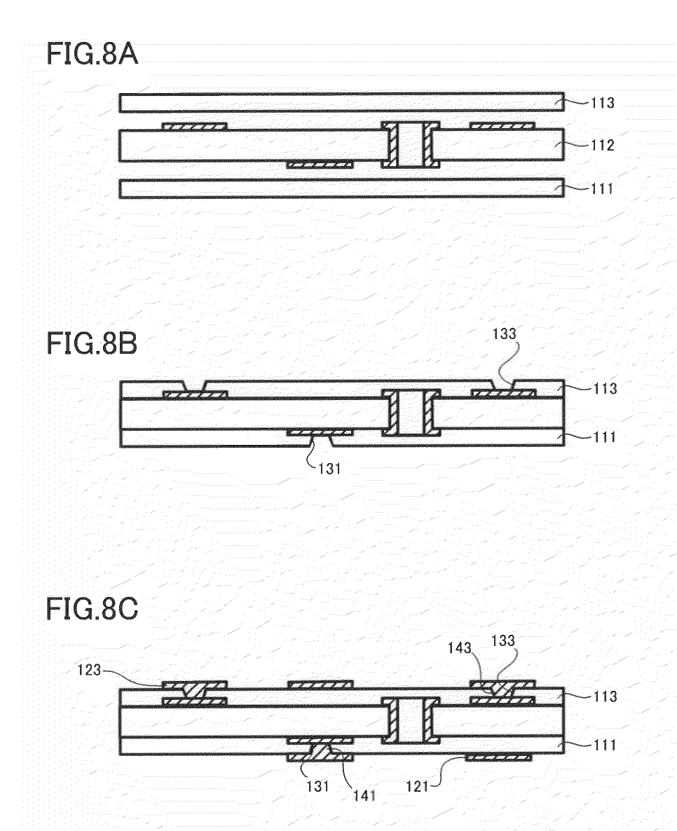

Subsequently, as shown in FIG. 8A, for example, the second insulating layer 113 and the first insulating layer 111 are disposed on the top and bottom sides of the wiring sub board. Then, they are pressed (e.g., hot-pressed). Thereafter, the resin is hardened in, for example, a heat treatment or the like, to solidify the first and second insulating layers 111 and 113. Then, after predetermined pre-processing, as shown in FIG. 8B, the via hole 131 is formed in the first insulating layer 111 and the via hole 133 is formed in the second insulating layer 113 with a laser, for example. Then, after desmearing (smear removal) and soft etching are carried out, PN plating (e.g., chemical copper plating and electric copper plating) is performed. As a result, a conductive film is formed on the entire surface of the wiring sub board including the via holes 131 and 133. Then, the conductive film on the surface of the wiring sub board is made thinner to a predetermined thickness by, for example, half etching, the conductive film is patterned as shown in FIG. 8C through, for example, a predetermined lithography process (pre-processing, lamination, exposure, development, etching, film separation, inspection of internal layers, etc.). As a result, the conductors 141 and 143, and the wiring layers 121 and 123 are formed. Thereafter, the top surfaces of the wiring layers 121 and 123 are processed to form rough surfaces. The wiring layers 121 and 123 can also be formed by printing a conductive paste (e.g., thermoset resin containing conductive particles) by, for example, screen printing.

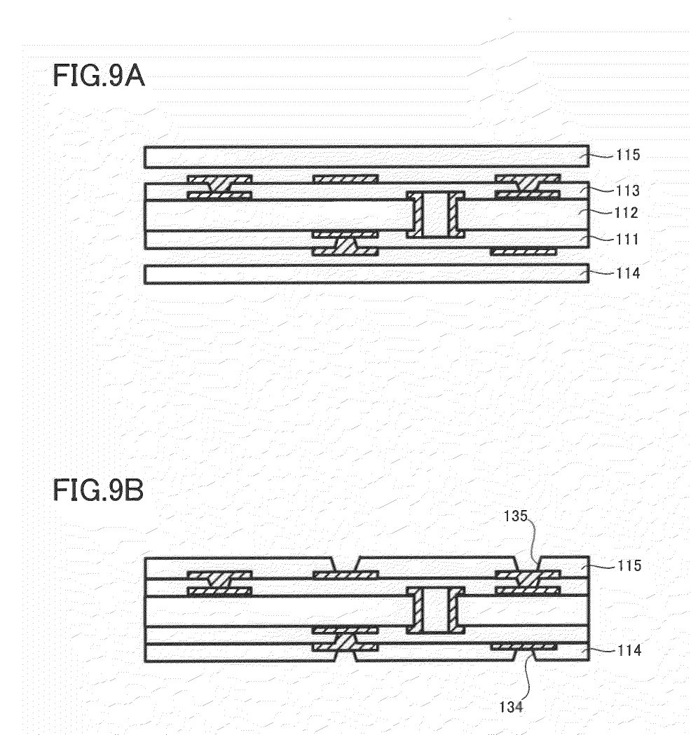

Subsequently, as shown in FIG. 9A, for example, the fourth insulating layer 115 and the third insulating layer 114 are disposed on the top and bottom sides of the wiring sub board. Then, they are pressed (e.g., hot-pressed). Thereafter, the resin is hardened in, for example, a heat treatment or the like, to solidify the third and fourth insulating layers 114 and 115. Then, after predetermined pre-processing, as shown in FIG. 9B, the via hole 134 is formed in the third insulating layer 114 and the via hole 135 is formed in the fourth insulating layer 115 with a laser, for example. Further, through steps similar to those shown in FIG. 8C, the conductors 144 and 145, and the wiring layers 124 and 125 as shown in FIG. 2A are formed. As a result, the wiring sub board 12 is produced at the production panel 100 as shown in FIG. 6.

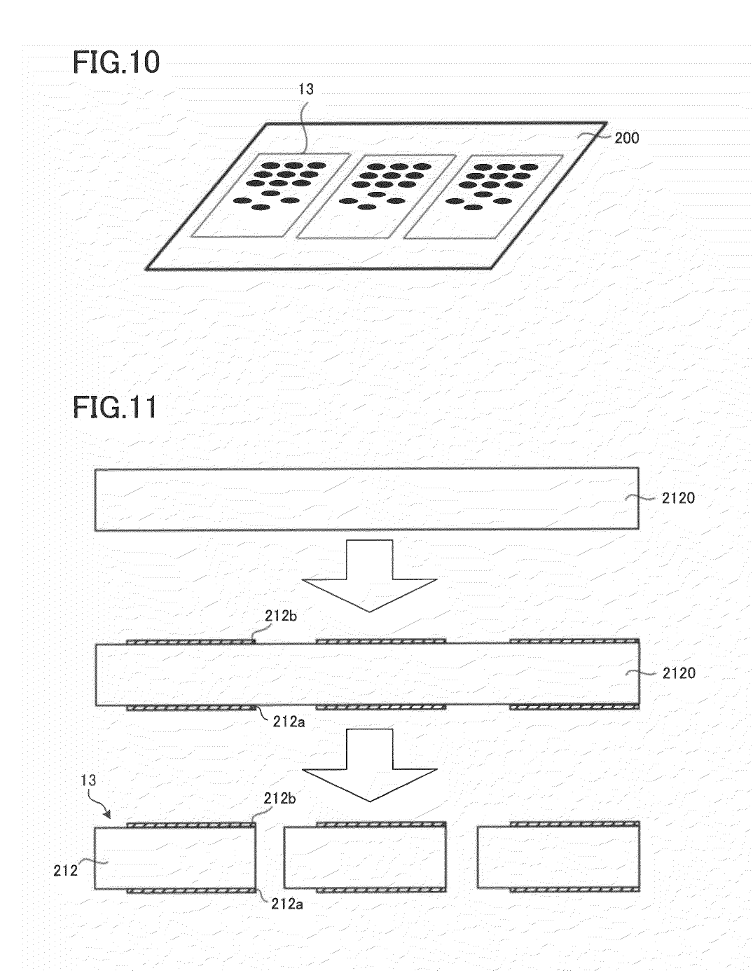

In addition, the wiring sub board is produced at a production panel 200 as shown in FIG. 10, for example. The production panel 200 is a dedicated production panel at which wiring sub boards having the same structure (structure shown in FIG. 2B) including the wiring sub board 13 are produced.

According to the fabrication method of the embodiment, the wiring sub board 13 is produced separately from the insulating board 11. This makes it possible to produce a larger number of wiring sub boards 13 at the production panel 200, thus improving the yield or the number of yielded products.

In producing the wiring sub board 13, conductive films are formed on the top and bottom sides of a material 2120 common to multiple products as shown in FIG. 11. Then, the conductive film is patterned through, for example, a predetermined lithography process (pre-processing, lamination, exposure, development, etching, film separation, inspection of internal layers, etc.), yielding the wiring layers 212a and 212b. Thereafter, the resultant structure is cut with a laser or the like, for example, to yield the wiring sub board 13 having a predetermined shape and size. As the material 2120, for example, a glass epoxy resin is used. Alternatively, a copper clad laminate may be used to omit the formation of the conductive film.

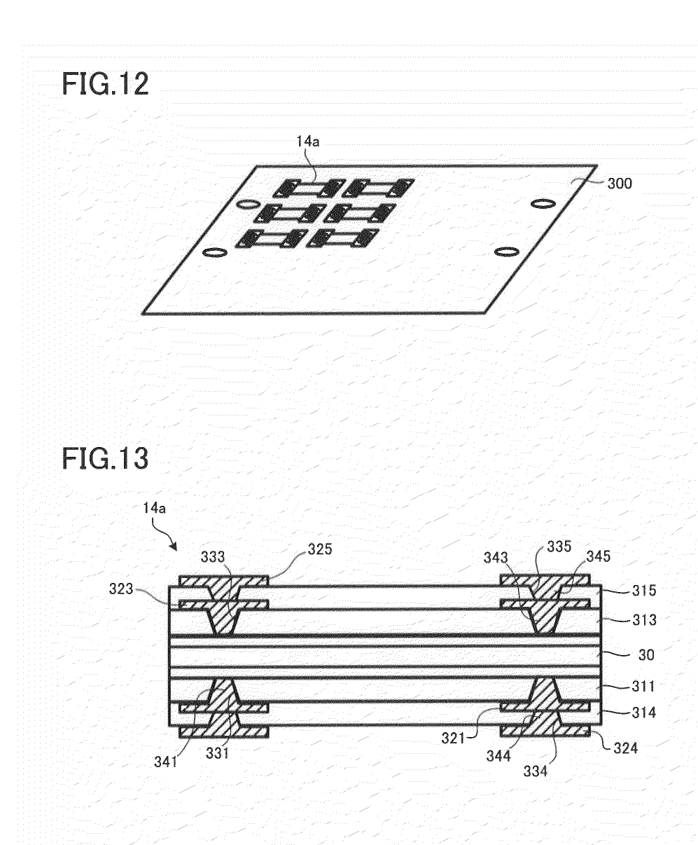

A wiring sub board 14a is also produced at a production panel 300 as shown in FIG. 12, for example. As shown in FIG. 13, the wiring sub board 14a is the wiring sub board 14 before the spaces R11 and R12 are removed therefrom. The production panel 300 is a dedicated production panel at which wiring sub boards having the same structure (structure shown in FIG. 13) including the wiring sub board 14a are produced.

According to the fabrication method of the embodiment, the wiring sub board 14a is produced separately from the insulating board 11. This makes it possible to produce a larger number of wiring sub boards 14a (eventually the wiring sub boards 14) at the production panel 300, thus improving the yield or the number of yielded products.

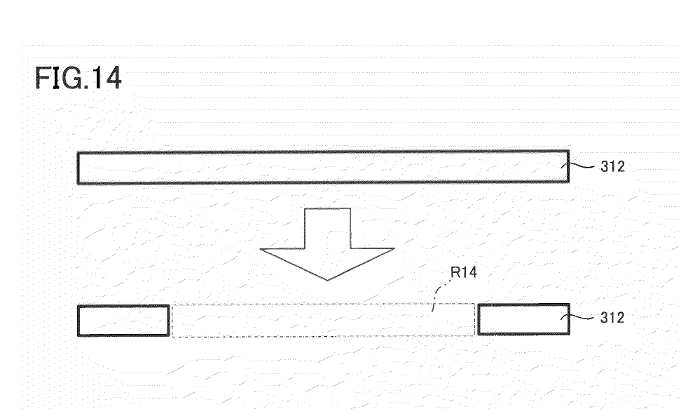

As shown in FIG. 14, the worker prepares a rigid base 312 made of a rigid insulating material, and cuts the rigid base 312 with, for example, a laser or the like, thus forming a space (clearance) R14. The rigid base 312 is made of a glass epoxy resin or the like with a thickness of, for example, about 50 to 150 μm, desirably about 100 μm. The rigid base 312 has substantially the same thickness as the flexible part 30.

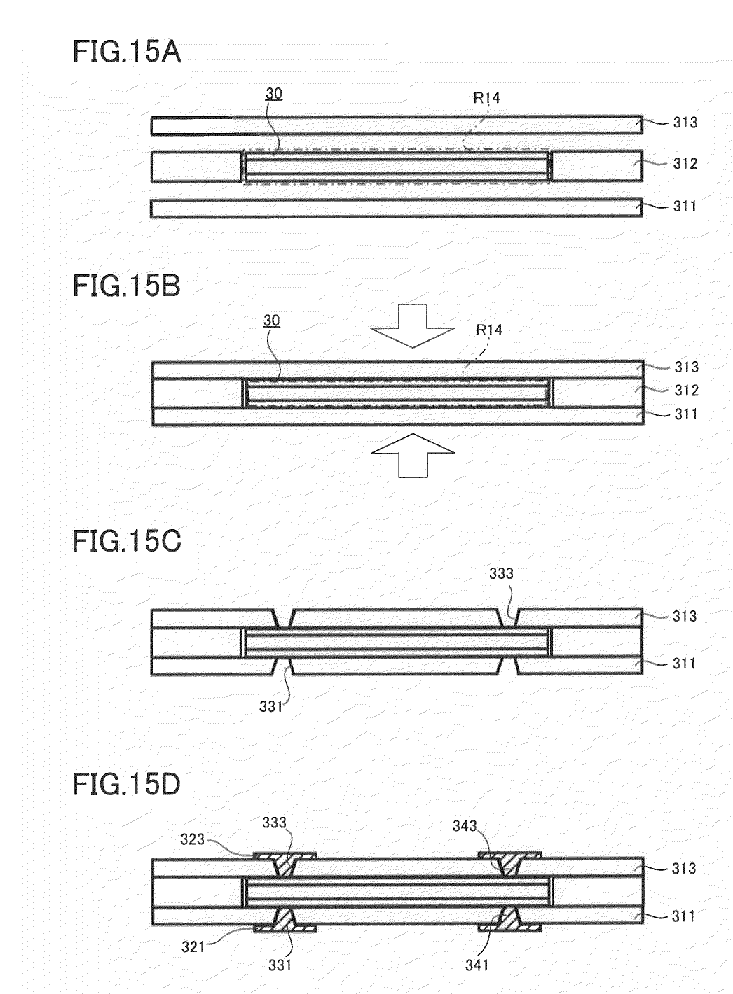

Next, the first and second insulating layers 311 and 313, the rigid base 312, and the flexible part 30 are aligned and laid out as shown in FIG. 15A, for example. That is, the flexible part 30 is arranged in the space R14 beside the rigid base 312. The boundary portion between the rigid base 312 and the flexible part 30 is covered with the first and second insulating layers 311 and 313. At this time, the individual end portions of the flexible part 30 are aligned, held between the first and second insulating layers 311 and 313. The center portion of the flexible part 30 is exposed between the rigid bases 312.

Next, with the positional alignment being done, the structure is pressed (e.g., hot-pressed) as shown in FIG. 15B. Accordingly, the resin 30c (FIG. 4) is extruded from the first and second insulating layers 311 and 313. That is, the pressing causes the resin 30c (insulating material) to leak out (flow out) from the prepregs constituting the first and second insulating layers 311 and 313 to be filled between the rigid base 312 and the flexible part 30. Thereafter, the first and second insulating layers 311 and 313 are solidified through, for example, a heat treatment or the like.

Subsequently, after predetermined pre-processing, as shown in FIG. 15C, the via hole 331 is formed in the first insulating layer 311 and the via hole 333 is formed in the second insulating layer 313 with, for example, a laser or the like. Then, after desmearing (smear removal) and soft etching are carried out, PN plating (e.g., chemical copper plating and electric copper plating) is performed. As a result, a conductive film is formed on the entire surface of the wiring sub board including the via holes 331 and 333. Then, the conductive film on the surface of the wiring sub board is made thinner to a predetermined thickness by, for example, half etching, the conductive film is patterned as shown in FIG. 15D through, for example, a predetermined lithography process (pre-processing, lamination, exposure, development, etching, film separation, inspection of internal layers, etc.). As a result, the conductors 341 and 343, and the wiring layers 321 and 323 are formed.

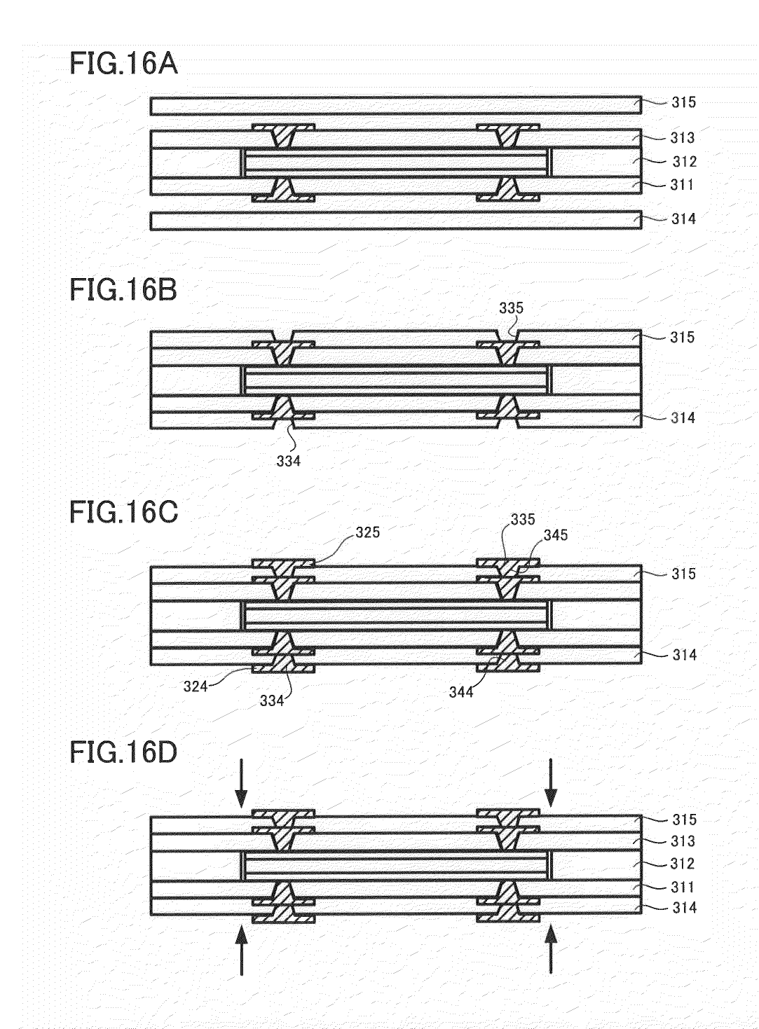

Subsequently, as shown in FIG. 16A, for example, the fourth insulating layer 315 and the third insulating layer 314 are disposed on the top and bottom sides of the wiring sub board. Then, they are pressed (e.g., hot-pressed). Thereafter, the resin is hardened in, for example, a heat treatment or the like, to solidify the third and fourth insulating layers 314 and 315. Then, after predetermined pre-processing, as shown in FIG. 16B, the via hole 334 is formed in the third insulating layer 314 and the via hole 335 is formed in the fourth insulating layer 315 with, for example, a laser or the like. Further, through steps similar to those shown in FIG. 15D, the conductors 344 and 345, and the wiring layers 324 and 325 are formed as shown in FIG. 16C.

Subsequently, the wiring sub board is cut with, for example, a laser or the like as shown in FIG. 16D, for example, thereby producing the wiring sub board 14a at the production panel 300 as shown in FIG. 12.

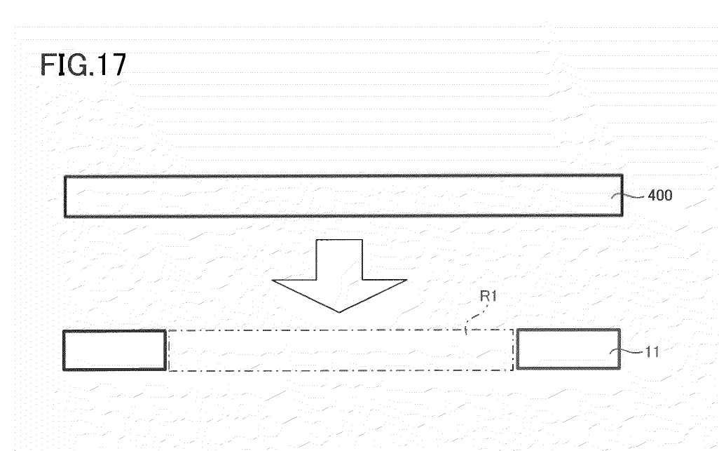

Before or after producing the wiring sub boards 12, 13, 14a, the worker produces the insulating board 11. Specifically, as shown in FIG. 17, a material (production panel 400) common to multiple products is cut with, for example, a laser or the like to form the space (clearance) R1. As a result, the insulating board 11 with a predetermined shape and size is produced. As the insulating board 11 is produced separately from the wiring sub boards 12, 13, 14a, an unnecessary laminate is not formed on the insulating board 11. This reduces the consumption of the conductive materials, insulating materials and so forth. This results in reduction in fabrication cost.

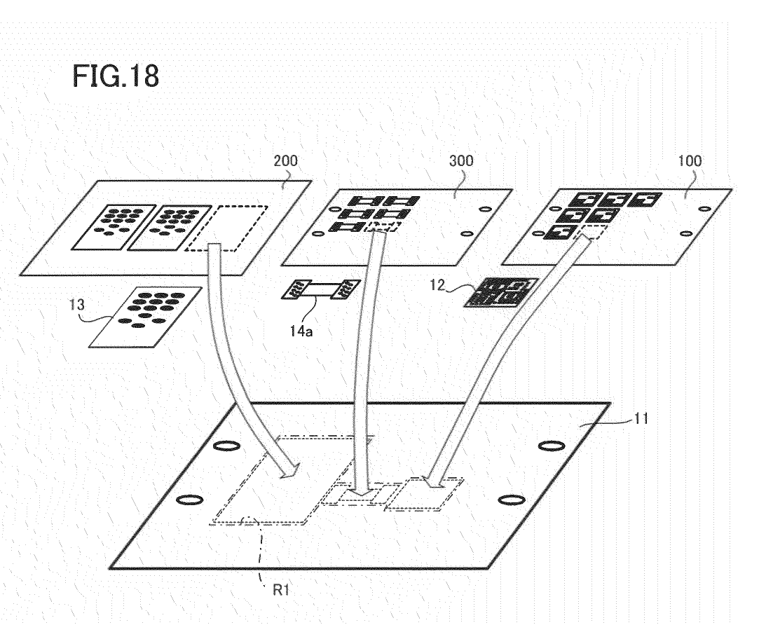

Next, the wiring sub boards 12, 13, 14a are respectively separated from the production panels 100, 200, 300, and are laid out in the space R1 of the insulating board 11 as shown in FIG. 18. At this time, an electrification test or the like is performed on the wiring sub boards 12, 13, 14a to remove any defective board, so that only defect-free boards are used.

According to the fabrication method of the embodiment, a defective board can be found and removed before forming the outermost layer, i.e., at an earlier stage. It is therefore possible to reduce the consumption of materials which would occur in case of defective boards present. This results in reduction in fabrication cost.

The positional alignment of the wiring sub boards 12, 13, 14a before forming the outermost layer can easily achieve high-precision alignment.

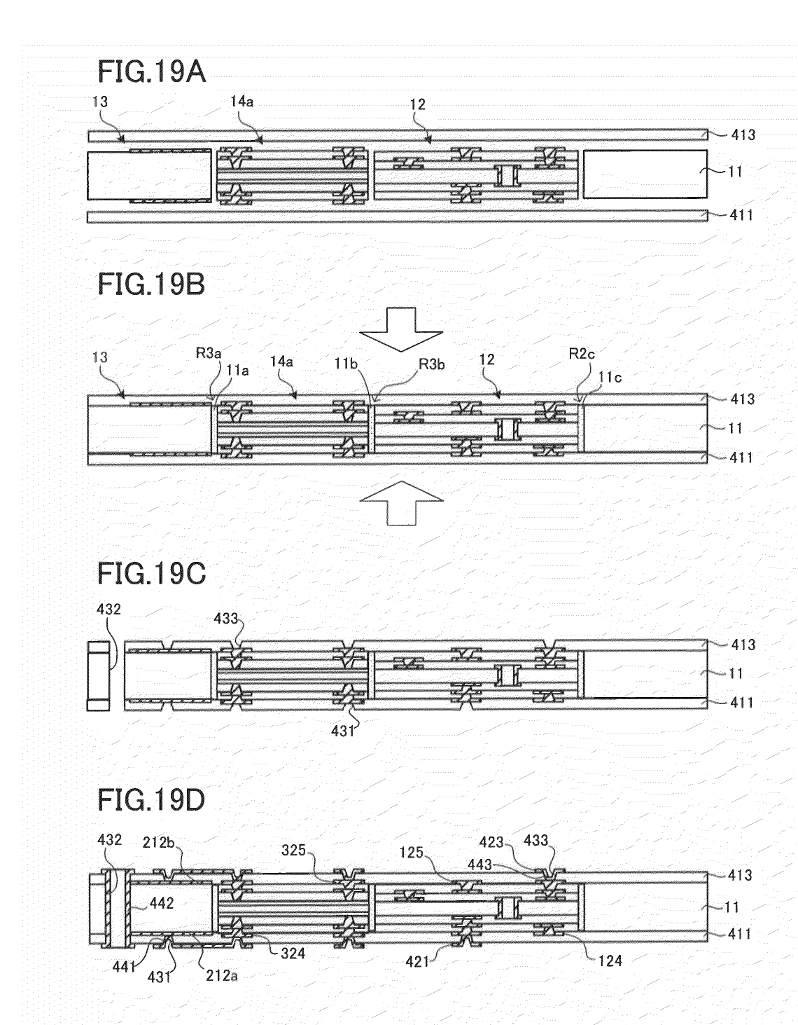

Subsequently, as shown in FIG. 19A, for example, the insulating layers 413, 411 are disposed on the top and bottom sides of the wiring sub boards 12, 13, 14a and the insulating board 11. Then, they are pressed (e.g., hot-pressed) as shown in FIG. 19B. Accordingly, the resins 11a to 11c (insulating materials) are extruded from the insulating layers 411 and 413. That is, the pressing causes the resins 11a to 11c to leak out (flow out) from the prepregs constituting the insulating layers 411 and 413 and to be filled in the first boundary portions R2a, R2b, R2c (FIG. 1A) between the insulating board 11 and the wiring sub boards 12, 13, 14a, and the second boundary portions R3a, R3b between the wiring sub boards 12, 13, 14a. As the insulating layers 413, 411 are formed on the top and bottom sides of the insulating board 11 and the wiring sub boards 12, 13, 14a at this time, the resins 11a to 11c are filled from both sides. Thereafter, the insulating layers 411 and 413 are solidified through, for example, a heat treatment or the like.

Subsequently, after predetermined pre-processing, as shown in FIG. 19C, the via hole 431 is formed in the insulating layer 411, the via hole 433 is formed in the insulating layer 413 and the through hole 432 penetrating the wiring board with, for example, a laser. Then, after desmearing (smear removal) and soft etching are carried out, PN plating (e.g., chemical copper plating and electric copper plating) is performed. As a result, a conductive film is formed on the entire surface of the wiring board including the via holes 431 and 433 and the through hole 432. Subsequently, the conductive film on the surface of the wiring sub board is made thinner to a predetermined thickness by, for example, half etching, the conductive film is patterned as shown in FIG. 19D through, for example, a predetermined lithography process (pre-processing, lamination, exposure, development, etching, film separation, inspection of internal layers, etc.). As a result, the wiring layers 421 and 423, the conductors 441 and 443, and the conductor 442 are formed.

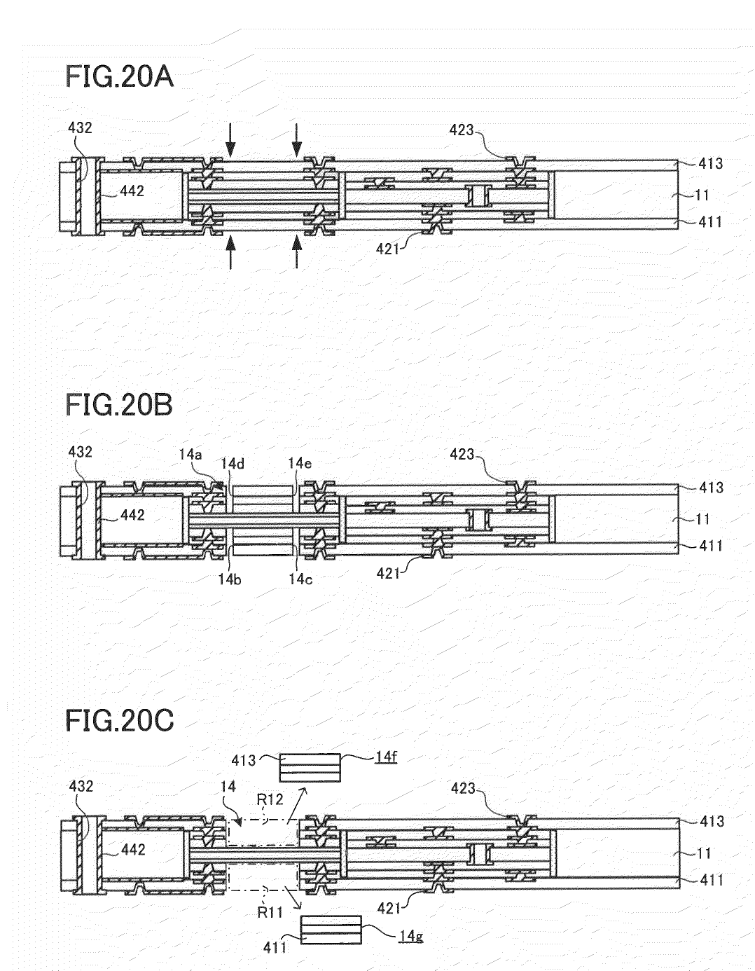

Then, after predetermined pre-processing, as shown in FIG. 20B, for example, cut lines 14b to 14e are formed in the insulating layer of the wiring sub board 14a with a laser or the like, for example, as shown in FIG. 20A, for example. Subsequently, as shown in FIG. 20C, structures 14f, 14g are removed as if they were pulled out from the top and bottom sides of the flexible part 30, respectively. As a result, the spaces R11 and R12 are formed in the center portion of the flexible part 30.

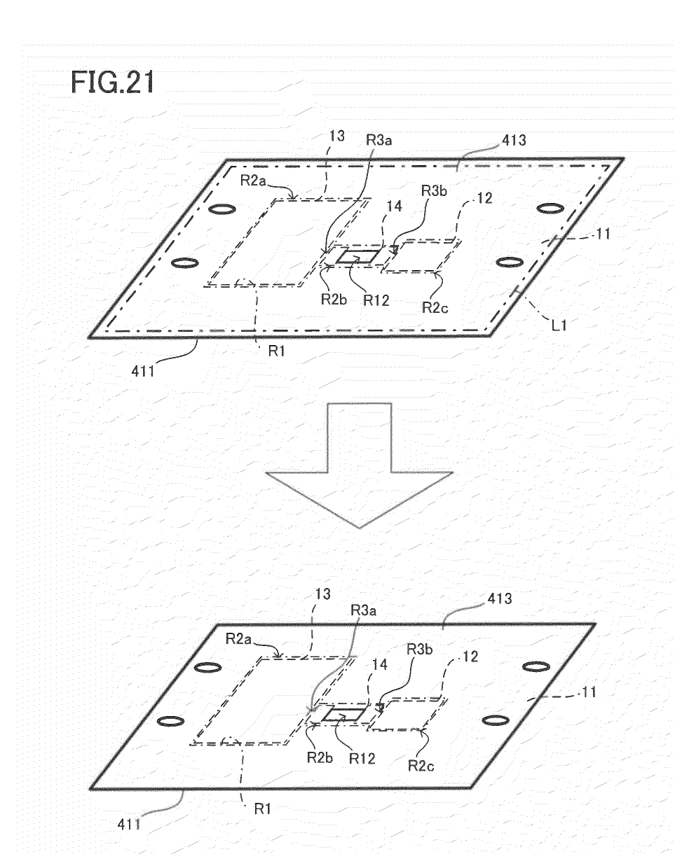

Thereafter, outline processing of the wiring board is performed as shown in, FIG. 21, using a router, for example. In the outline processing, a part of the insulating board is cut out like a cut line L1 in the diagram to process the wiring board to a predetermined shape (e.g., quadrate shape).

The wiring board 10 shown in FIG. 5 is fabricated this way. That is, the insulating layers 411 and 413, and the wiring layers 421 and 423 in the wiring board 10 become the outermost layers.

While the wiring board and fabrication method therefor according to the embodiment have been described, the present invention is not limited to the embodiment.

The wiring sub boards 12, 13, 14 are not electrically connected to one another in the embodiment, which is not restrictive. For example, the wiring sub boards 12, 13, 14 may be electrically connected to one another according to the purpose or the like.

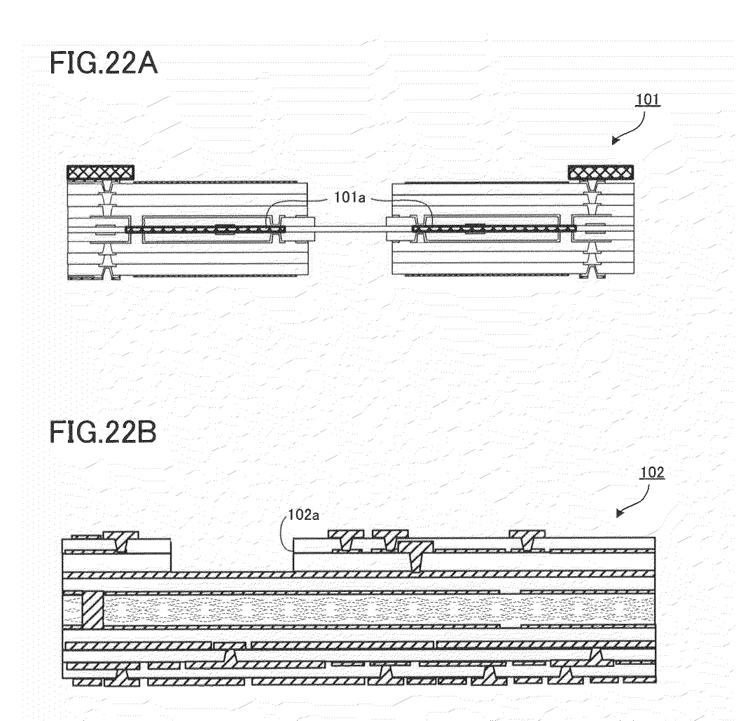

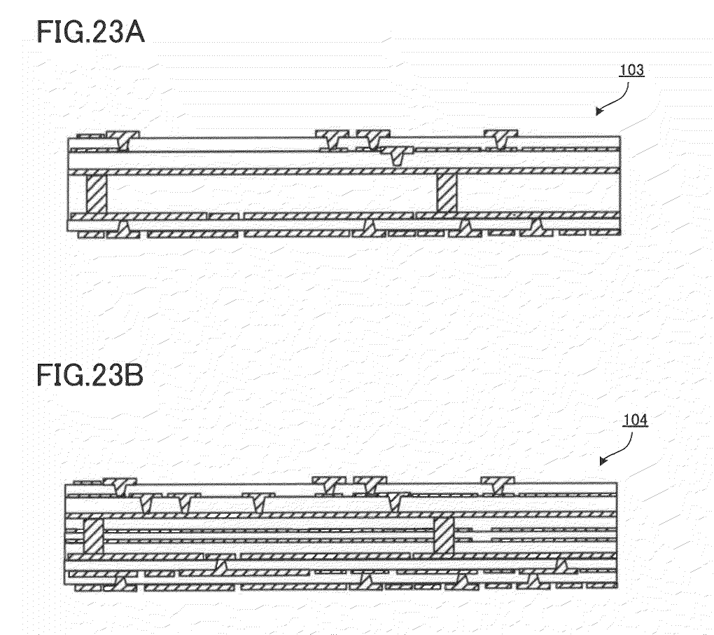

The wiring sub boards 12, 13, 14 are not limited to those shown in FIGS. 2A to 2C. For example, the boards may be flexible wiring sub boards. Further, the boards may be a wiring sub board 101 incorporating an electronic part 101a as shown in FIG. 22A, for example. As another option, the boards may be a wiring sub board 102 having a cavity 102a formed in the top surface thereof. Those different types of wiring sub boards may be combined on the wiring board 10. Further, in the combination of different types of wiring sub boards or the combination of wiring sub boards of the same type, a low-density wiring sub board 103 as shown in FIG. 23A, for example, and a high-density wiring sub board 104 as shown in FIG. 23B, for example, may be combined. The low-density wiring sub board is a wiring sub board having a lower wiring density than the high-density wiring sub board. The wiring sub board may be a one-side wiring sub board having wiring layers and insulating layers laminated on one side of the core.

The materials and sizes of the individual layers, the number of the layers, and so forth can be changed in the embodiment.

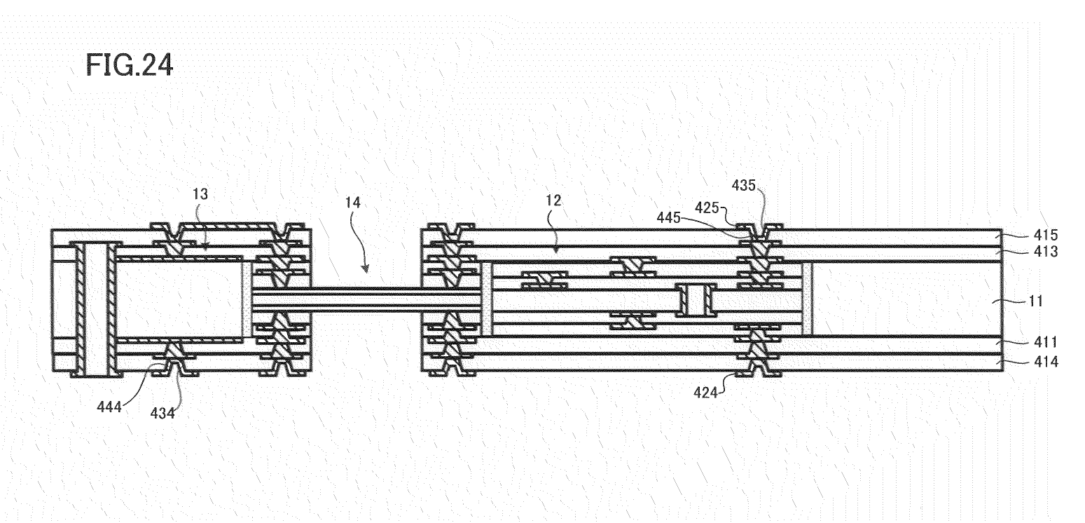

For example, single-layer insulating layers, i.e., the insulating layers 413, 411 are formed on the top and bottom sides of the insulating board 11 and the wiring sub boards 12, 13, 14 in the embodiment, which is not restrictive. For example, as shown in FIG. 24, multiple insulating layers of different materials, i.e., the insulating layers 413 and 415 and the insulating layers 411 and 414 may be formed on the top and bottom sides of the insulating board 11 and the wiring sub boards 12, 13, 14.

Although the wiring board 10 having three wiring sub boards 12, 13, 14 is exemplified in the foregoing description of the embodiment, the number of wiring sub boards is optional. That is, the quantity may be one, two, or four or greater.

The sequential order of the processes in the embodiment can be changed without departing from the scope and spirit of the invention. Some processes may be omitted according to the purpose or the like.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board comprising:
a plurality of wiring sub boards being laid out side by side with each other and having conductive patterns;
an insulating board being laid out alongside of one of the plurality of wiring sub boards; and
a plurality of insulating layers comprising an insulating material and having via holes in which conductors electrically connected to the conductive patterns are formed by plating, the insulating layers continuously extending from the insulating board to the wiring sub boards so as to respectively cover a first boundary portion between the insulating board and each of the wiring sub boards, and a second boundary portion between the wiring sub boards,
wherein the first boundary portion and the second boundary portion are filled with the insulating material of the insulating layers.

2. The wiring board according to claim 1, wherein the wiring sub boards include a plurality of rigid wiring sub boards, a flexible wiring sub board, a flex-rigid wiring sub board, a wiring sub board incorporating an electronic part, and a wiring sub board having a cavity formed therein.

3. The wiring board according to claim 1, wherein the plurality of wiring sub boards include a high-density wiring sub board and a low-density wiring sub board.

4. The wiring board according to claim 1, wherein the insulating layers each contain a resin as the insulating material.

5. The wiring board according to claim 1, wherein the insulating layers is formed on both sides of the insulating board and the plurality of wiring sub boards.

6. The wiring board according to claim 1, wherein the wiring sub boards are not electrically connected to one another.

7. The wiring board according to claim 1, wherein the insulating layers each comprise a plurality of insulating materials.

8. The wiring board according to claim 1, wherein the insulating layers constitute part of the insulating layers of the wiring board.

9. A method for fabricating a wiring board, comprising:
horizontally laying an insulating board and a plurality of wiring sub boards having conductive patterns;
laying insulating layers to respectively cover a first boundary portion between the insulating board and each of the wiring sub boards, and a second boundary portion between the wiring sub boards;
filling an insulating material for the insulating layers in the first boundary portion and the second boundary portion;
forming via holes in the insulating layers and forming conductors in the via holes by plating; and
electrically connecting the conductors formed in the via holes to the conductive patterns.

10. The method according to claim 9, wherein the plurality of wiring sub boards include a plurality of rigid wiring sub boards, a flexible wiring sub board, a flex-rigid wiring sub board, a wiring sub board incorporating an electronic part, and a wiring sub board having a cavity formed therein.

11. The method according to claim 9, wherein the plurality of wiring sub boards include a high-density wiring sub board and a low-density wiring sub board.

12. The method according to claim 9, further comprising carrying out outline processing of the wiring board.

13. The method according to claim 9, wherein the insulating layers are pressed to extrude therefrom the insulating material which fills a space between the insulating board and the wiring sub boards.

14. The method according to claim 9, further comprising producing the insulating board and the plurality of wiring sub boards by using separate production panels, respectively.

15. The method according to claim 12, wherein the outline processing is router processing.
